(19) United States
(12) Patent Application Publication
(10) Pub. No.: US 2005/0133819 A1
(43) Pub. Date: Jun. 23, 2005

(54) Semiconductor device using strained silicon layer and method of manufacturing the same

(76) Inventor: Hirohisa Kawasaki, Yokohama-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 10/972,001

(22) Filed: Oct. 25, 2004

(30) Foreign Application Priority Data
Nov. 7, 2003 (JP) 2003-378629

(51) Int. Cl. H01L 29/10

(52) U.S. Cl. 257/195

(57) ABSTRACT

A semiconductor device includes a substrate-strained Si formed of a first semiconductor layer which has a first lattice constant and formed on a semiconductor substrate, and a second semiconductor layer which has a second lattice constant and epitaxially grows such that a lattice of the second semiconductor layer matches that of the first semiconductor layer. The semiconductor device further includes a first conductive type metal oxide semiconductor (MOS) transistor which is formed in a first region on the substrate-strained Si and has the second semiconductor layer modified so as to have a first thickness, and a second conductive type MOS transistor which is formed in a second region on the substrate-strained Si and has the second semiconductor layer modified-so as to have a second thickness thinner than the first thickness.

### CROSS-REFERENCE TO RELATED APPLICATIONS

This application is based upon and claims the benefit of priority from prior Japanese Patent Application No. 2003-378629 filed Nov. 7, 2003, the entire contents of which are incorporated herein by reference.

### BACKGROUND OF THE INVENTION

1. Field of the Invention

The present invention relates to a semiconductor device using a strained silicon layer and a method of manufacturing the semiconductor device. More particularly, the present invention relates to a complementary metal oxide semiconductor (CMOS) device using a substrate-strained Si, which is formed by stacking a silicon germanium (SiGe) layer and a silicon layer (strained Si layer) on the surface of a Si substrate.

2. Description of the Related Art

Recently, a technique for forming a CMOS device using a substrate-strained Si formed by stacking a SiGe layer and Si layer on a Si substrate has been proposed (for example, Japanese Patent Application KOKAI Publication No. 2002-280568). In the substrate-strained Si, since the Si layer epitaxially grows on the SiGe layer whose lattice constant is larger than the Si layer, the crystalline structure of the Si layer is strained. Therefore the Si layer is called a “strained Si layer”.

When the strained Si layer is employed in manufacturing a semiconductor device, it is said that the thicker the strained Si layer, the better. This is because the strained Si layer is reduced in thickness by being oxidized and by diffusion of Ge from the SiGe layer. However, it was experimentally confirmed that the degree of internal strain (stress) of the strained Si layer gradually decreases in the course of the manufacturing process, such as oxidation and reactive ion etching (RIE), for a metal oxide semiconductor field effect transistor (MOSFET). Furthermore, the degree of internal strain decreases with the distance from the interface between the strained Si layer and the SiGe layer.

The stress of the strained Si layer increases virtually in proportional to the Ge concentration of the SiGe layer. It is experimentally found that the strain relaxation (reduction) can be prevented by reducing the thickness of the strained Si layer. However, since the electron and hole mobilities increase in different manners with respect to the stress of the strained Si layer, the effective thickness of the strained Si layer required for preventing the relaxation of the strained Si layer varies between an n-channel MOS (hereinafter referred to as an “NMOS”) transistor and a p-channel MOS (hereinafter referred to as a “PMOS”) transistor. Even though the thickness of the strained Si layer is reduced if the strained Si layers used in the NMOS transistor and the PMOS transistor have the same thickness, the MOSFETs (NMOS transistor and PMOS transistor) will not exhibit maximum performance.

On the other hand, the diffusion coefficients of impurities such as boron (B), arsenic (As), and phosphorus (P) differ between in the SiGe layer and in the Si layer. To be more specific, the diffusion coefficient of a p-type impurity such as B in the SiGe layer is known to be about ⅓ to ⅕ as small as in the Si layer. In contrast, the diffusion coefficient of an n-type impurity such as As or P in the SiGe layer is know to be about 5 to 8 times as large as in the Si layer. Therefore, when the substrate-strained Si of a SiGe layer+Si layer (strained Si layer) is used in an NMOS transistor and a PMOS transistor, if the strained Si layers used in both transistors have the same thickness, the NMOS and PMOS transistors will differ in short-channel effect. This is not preferable for short channel CMOS devices.

Next, contact resistance will be discussed taking the contact called substrate contact, which connects between the contact to be connected to an upper-layer metal wiring element and a silicide compound on a diffusion layer, as an example. Usually the substrate contact is the Schottky contact formed between a metal (via) and a semiconductor (silicide compound). To obtain the ohmic contact between the metal and the semiconductor, it is preferable that an NMOS transistor satisfy the relationship: φ[metal]<φ[semiconductor] and a PMOS transistor satisfy the relationship: φ[metal]>φ[semiconductor], where φ is work function. However, when the strained Si layers of the NMOS transistor and PMOS transistor have the same thickness, it is difficult to bring the substrate contact into ohmic contact.

As described, when a MOSFET is formed using a substrate-strained Si composed of the SiGe layer and the strained Si layer, if the strained Si layers of an NMOS transistor and PMOS transistor have the same thickness, the MOSFET cannot exhibit the maximum performance.

### BRIEF SUMMARY OF THE INVENTION

According to a first aspect of the present invention, there is provide a semiconductor device comprising: a substrate-strained Si formed of a first semiconductor layer which has a first lattice constant and formed on a semiconductor substrate, and a second semiconductor layer which has a second lattice constant and epitaxially grows such that a lattice of the second semiconductor layer matches that of the first semiconductor layer; a first conductive type metal oxide semiconductor (MOS) transistor which is formed in a first region on the substrate-strained Si and has the second semiconductor layer modified so as to have a first thickness; and a second conductive type MOS transistor which is formed in a second region on the substrate-strained Si and has the second semiconductor layer modified so as to have a second thickness thinner than the first thickness.

According to a second aspect of the present invention, there is provided a method of manufacturing a semiconductor device using a substrate-strained Si by stacking a first semiconductor layer and a second semiconductor layer sequentially in this order on a surface of a semiconductor substrate comprising: oxidizing a surface portion of the second semiconductor layer, removing an oxide film formed on the surface portion of the second semiconductor layer; forming an anti-oxide film on the surface portion of the second semiconductor layer corresponding to the first region; oxidizing the surface portion of the second semiconductor layer corresponding to the second region except the first region on the substrate-strained Si with the anti-oxide film as a mask; removing the oxide film formed by oxidation on the surface portion of the second semiconductor layer corresponding to the second region; and forming a first conductive type metal oxide semiconductor (MOS) transistor having the second semiconductor layer of a first thickness in the first region on the substrate-strained Si, and forming a second conductive type MOS transistor having the second semiconductor layer of a second thickness in the second region on the substrate-strained Si, the second thickness being thinner than the first thickness.

According to a third aspect of the present invention, there is provided a method of manufacturing a semiconductor device using a substrate-strained Si by stacking a first semiconductor layer and a second semiconductor layer sequentially in this order on a surface of a semiconductor substrate comprising: oxidizing a surface portion of the second semiconductor layer; removing an oxide film formed on the surface portion of the second semiconductor layer; selectively growing only the second semiconductor layer corresponding to at least a first region on the substrate-strained Si; and forming a first conductive type metal oxide semiconductor (MOS) transistor having the second semiconductor layer of a first thickness in the first region on the substrate-strained Si, and forming a second conductive type MOS transistor having the second semiconductor layer of a second thickness in the second region on the substrate-strained Si, the second thickness being thinner than the first thickness.

### BRIEF DESCRIPTION OF THE SEVERAL VIEWS OF THE DRAWING

FIG. 1 is a sectional view illustrating a basic structure of a semiconductor, for example, a CMOS device, according to an embodiment of the present invention;

FIG. 2 is a graph showing the relationship between the Ge concentration of a Si₁₋ₓ Geₓ (0≦x<1) layer and the critical thickness of the strained Si layer in the CMOS device of FIG. 1;

FIG. 3 is a sectional view of a step of a manufacturing method of the CMOS device of FIG. 1;

FIG. 4 is a sectional view of a step of a manufacturing method of the CMOS device of FIG. 1;

FIG. 5 is a sectional view of a step of a manufacturing method of the CMOS device of FIG. 1;

FIG. 6 is a sectional view of a step of a manufacturing method of the CMOS device of FIG. 1;

FIG. 7 is a sectional view of a step of a manufacturing method of the CMOS device of FIG. 1;

FIGS. 8A and 8B are a views and a graph showing the relationship between the thickness of the strained Si layer and the strain-relaxation amount;

FIG. 9 is a graph showing the profile of the improving rate of hole and electron mobility versus the Ge concentration of the SiGe layer in the CMOS device of FIG. 1;

FIG. 10 is a sectional view showing the CMOS device of FIG. 1 in which a substrate contact is further formed thereon;

FIG. 11 is a sectional view of an NMOS transistor for illustrating the contact resistance of the substrate contact;

FIG. 12 is a sectional view of a PMOS transistor for illustrating the contact resistance of the substrate contact;

FIG. 13 is a sectional view of a step of another method of manufacturing the CMOS device shown in FIG. 1;

FIG. 14 is a sectional view of a step of another manufacturing method of the CMOS device of FIG. 1;

FIG. 15 is a sectional view of a step of another manufacturing method of the CMOS device of FIG. 1; and

FIG. 16 is a sectional view of another structure of a substrate-strained Si to be applied to the CMOS device of FIG. 1.

### DETAILED DESCRIPTION OF THE INVENTION

The embodiments of the present invention will be described with reference to the drawings.

### EMBODIMENTS

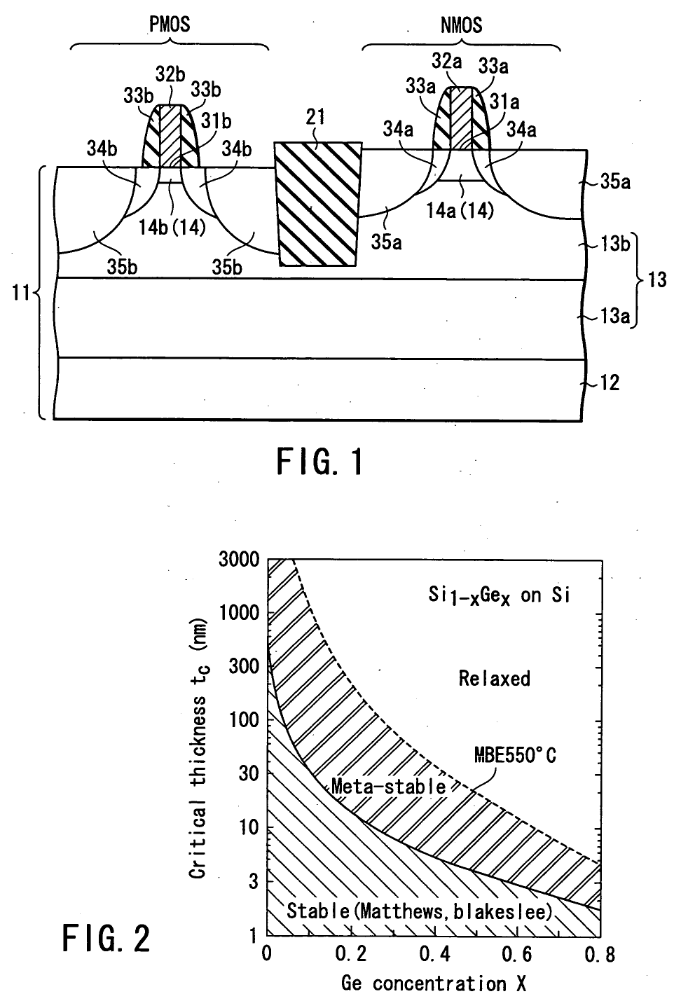

FIG. 1 shows a basic structure of a semiconductor device according to an embodiment of the present invention. Explanation will be made by taking a complementary MOS (CMOS) device as an example. The substrate used herein is a so-called substrate-strained Si in which a silicon germanium (SiGe) layer is formed on a silicon (Si) substrate without an insulating layer interposed between them.

As shown in FIG. 1, in the surface of a substrate-strained Si 11, an element isolating dielectric region 21, a shallow trench isolation (STI), is selectively formed. The substrate-strained Si 11 is formed by epitaxially growing a strained Si layer 14 (second semiconductor layer) having a second lattice constant on a semiconductor substrate, a Si substrate 12, with a SiGe layer 13 (a first semiconductor layer) having a first lattice constant interposed therein. The SiGe layer 13 is constituted of a SiGe_{0→x} layer 13a (lattice-strain buffer layer) having a Ge (0→x) concentration of about 0% to 30% and Si₁₋ₓGeₓ (0≦x<1) layer 13b (lattice-strain relaxation layer) stacked on the SiGe_{0→x} layer 13a. The Ge concentration of the SiGe_{0→x} layer 13a gradually reduces toward the interface with the Si substrate 12, thereby serving as a lattice-strain buffer layer.

In the first region on the substrate-strained Si 11 defined by the element isolating dielectric region 21, an n-channel MOS (NMOS) transistor (a first conductive type MOS transistor) is formed. The NMOS transistor has a strained Si layer 14a having a first thickness. On the strained Si layer 14a, that is, on the surface of the substrate-strained Si 11, a gate electrode 32a is selectively formed with a gate oxide film 31a interposed between them. On each of the sidewalls of the gate electrode 32a and the gate oxide film 31a, a sidewall insulation layer 33a is formed. Furthermore, in the surface of the substrate-strained Si 11 except for the region having the gate electrode 32a formed thereon, an extension region 34a and a diffusion layer region 35a are formed as the source and drain.

On the other hand, in the second region on the substrate-strained Si 11 defined by the element isolating dielectric region 21, a p-channel MOS (PMOS) transistor (a second conductive type MOS transistor) is formed. The PMOS transistor has a strained Si layer 14b having a second thickness. On the strained Si layer 14b, that is, on the surface of the substrate-strained Si 11, a gate electrode 32b is selectively formed with a gate oxide film 31b interposed between them. On the sidewall of the gate electrode 32b and the gate oxide film 31b, a sidewall insulation layer 33b is formed. Furthermore, in the surface of the substrate-strained Si 11 except for the region having the gate electrode 32b formed thereon, an extension region 34b and a diffusion layer region 35b are formed as the source and drain.

In this embodiment, the thickness of the strained Si layer 14b of the PMOS transistor is set at, for example, 3 nm (preferable about 2 to 5 nm). The thickness is sufficient not only to form a channel region but also to prevent the effect of interface state generated between the strained Si layer 14b and the Si₁₋ₓGeₓ (0≦x<1) layer 13b. In contrast, the thickness of the strained Si layer 14a of the NMOS transistor is larger than, for example, that of the strained Si layer 14b, and equal or smaller than the critical thickness t_{c} of the strained Si layer 14 epitaxially grown on the Si₁₋ₓGeₓ (0≦x<1) layer 13b.

The critical thickness t_{c} of the strained Si layer 14 varies depending upon the Ge concentration x of the Si₁₋ₓGeₓ (0≦x<1) layer 13b. For example, when the Ge concentration is 20% (x=0.2), the critical thickness t_{c} is about 15 nm, as shown in FIG. 2. Therefore, when the Ge concentration of the Si₁₋ₓGeₓ (0≦x<1) layer 13b is 20%, the strained Si layer 14a is formed with a thickness of 3 nm or more and 15 nm or less.

Next, a method of manufacturing the CMOS device having the aforementioned structure will be explained. In this method, before the gate electrodes 32a and 32b are formed on the substrate-strained Si 11 formed by stacking the SiGe layer 13 and the strained Si layer 14 on the Si substrate 12, the thickness of the strained Si layer 14 is controlled by Si oxidation.

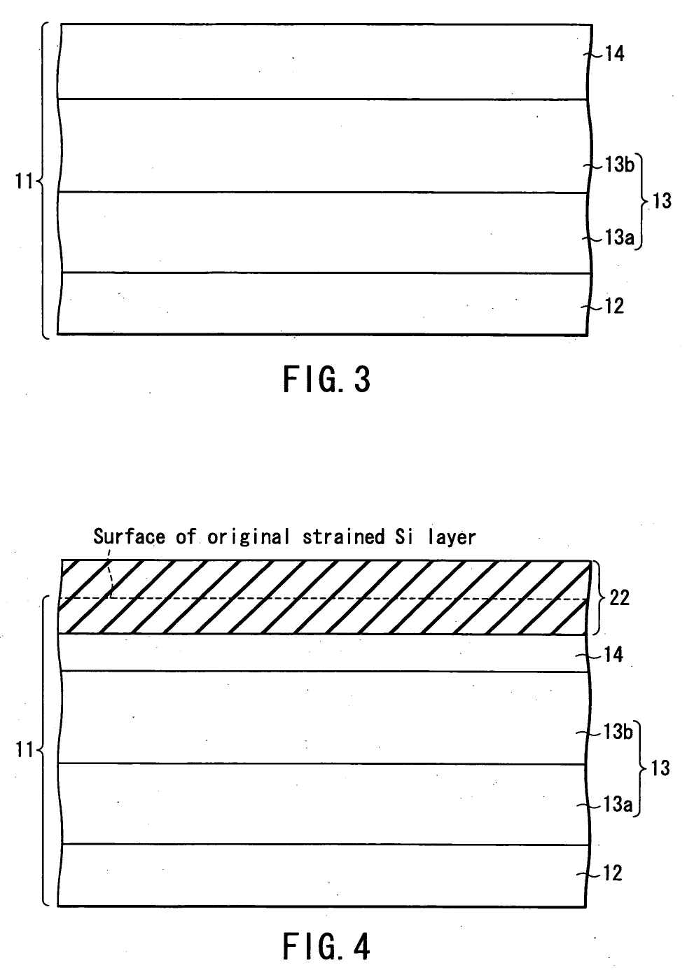

At the outset, the SiGe layer 13 and the strained Si layer 14 are stacked on the Si substrate 12 to prepare a wafer-form substrate-strained Si 11 (see FIG. 3). In the substrate-strained Si 11, an element isolating dielectric region (not shown) is formed and simultaneously Si oxidation is applied to obtain a uniformly oxidized wafer plane (see FIG. 4). At this time, the Si oxide (SiO₂) film 22 is controlled such that the thickness of the strained Si layer 14 becomes equal to the predetermined thickness (the first thickness) of the strained Si layer 14a of the NMOS transistor, in consideration of the amount of Si to be consumed by a later oxidation process for manufacturing a MOSFET.

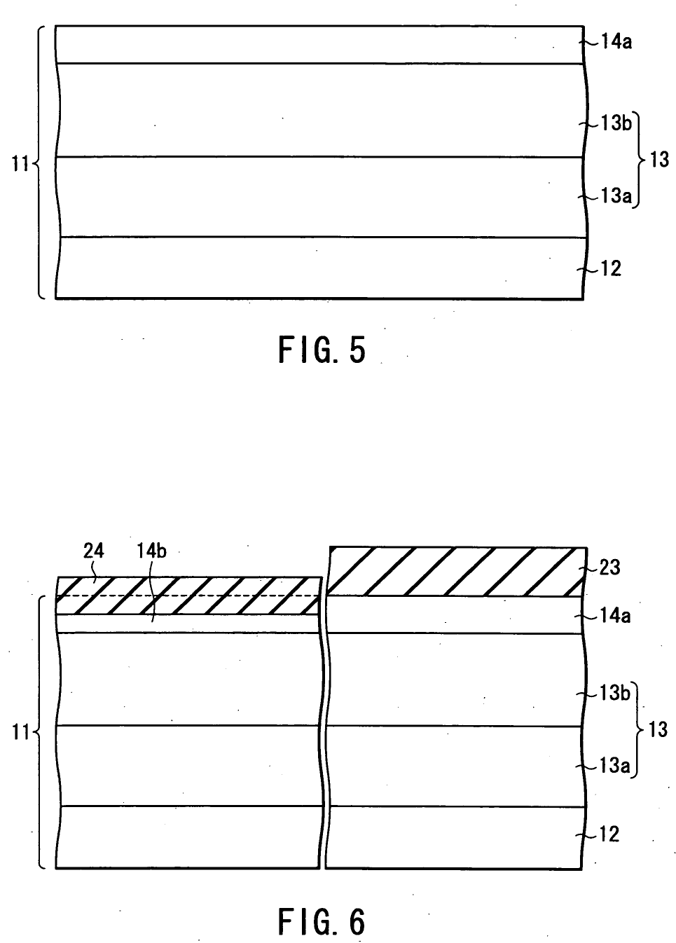

Subsequently, the SiO₂ film 22 is completely removed (see FIG. 5) and then a mask formed of a film having oxidation resistance, e.g., a silicon nitride (SiN) film 23, is formed on the upper surface of the substrate-strained Si 11 corresponding to the first region in which the NMOS transistor is to be formed (see FIG. 6). Thereafter, the thickness of a SiO₂ film 24 to be formed only on the upper surface of the substrate-strained Si 11 corresponding to the second region is controlled such that the thickness of the strained Si film 14 of the second region (uncovered with the mask) becomes equal to the predetermined thickness (second thickness) of the strained Si layer 14b of the PMOS transistor in consideration of the consumed amount of Si during the oxidation process later performed for forming a MOSFET.

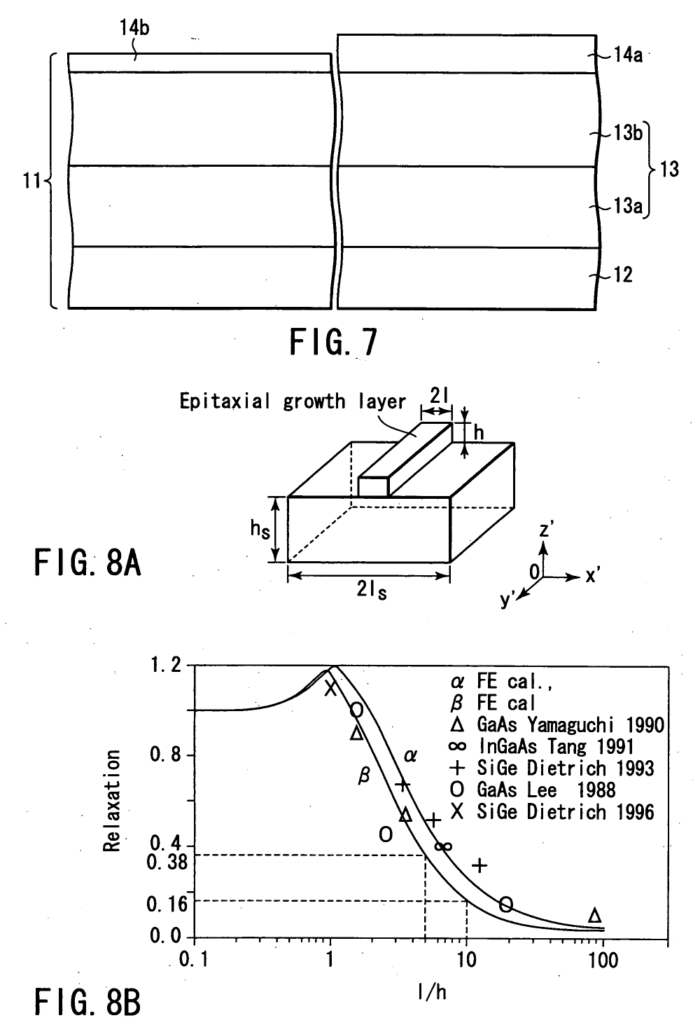

Thereafter, both the SiN film 23 and the SiO₂ film 24 are completely removed. As a result, the substrate-strained Si 11 having the strained Si layers 14a and 14b different in thickness can be obtained, for example, shown in FIG. 7. The difference in thickness between the strained Si layers 14a and 14b may be further increased by repeating the aforementioned process. On the substrate-strained Si 11 thus obtained, more specifically, on the first region of the substrate-strained Si 11 in which the strained Si layer 14a is formed, and on the second region of the substrate-strained Si 11 in which the strained Si layer 14b is formed, an NMOS transistor and a PMOS transistor are respectively formed in accordance with a known MOSFET manufacturing process. As a result, the CMOS device having the structure shown in FIG. 1 is accomplished.

Next, in the case where an NMOS transistor having the thicker strained Si layer 14a and a PMOS transistor having the thinner strained Si layer 14b are formed in the same substrate-strained Si 11, how to diffuse impurities in the strained Si layer 14 and the SiGe layer 13 will be explained. It is said that the diffusion coefficient of an n-type impurity such as arsenic (As) or phosphorus (P) in the SiGe layer 13 becomes as about 5 to 8 times as large as in the strained Si layer 14. On the other hand, it is reported that the diffusion coefficient of a p-type impurity such as boron (B) in the SiGe layer 13 becomes as about ⅓ to ⅕ times as small as in the strained Si layer 14. Therefore, in the case of the NMOS transistor, impurity ions doped in the extension region (34a) formation region can be suppressed from diffusing into the SiGe layer 13 having a large diffusion coefficient by increasing the thickness of the strained Si layer 14a. In other words, the thicker the strained Si layer 14a of the NMOS transistor, the better in suppressing the short-channel effect. Conversely, in the case of the PMOS transistor, the thinner the thickness of the strained Si layer 14b, the better in suppressing the short-channel effect.

As described in the above, the strained Si layer 14a of the NMOS transistor is formed thick, whereas the strained Si layer 14b of the PMOS transistor is formed thin. In this manner, the short-channel effect of the NMOS and PMOS transistors can be suppressed more. As a result, when ions are doped in order to form the channel region and Halo region, the dose amount of the ions can be reduced, thereby improving a current driving force became of the decrease of impurity scattering. More specifically, since the SiGe layer 13 has a larger n-type impurity diffusion coefficient than the strained Si layer 14, the extension profile of the extension region 34a in the SiGe layer 13 is likely longer than that of the extension region 34b, if the SiGe layer 13 is present alone (that is, if the strained Si layers 14a and 14b have the same thickness or there are no strained Si layers 14a and 14b). However, the size of the extension region formed in the SiGe layer 13 is larger in the PMOS transistor than that in the NMOS transistor. That is, the extension region 34a is not extremely larger than the extension region 34b. Therefore, it is possible to form a shallow junction in both in the NMOS transistor employing impurities having a high diffusion rate and in the PMOS transistor employing impurities having a low diffusion rate in the SiGe layer 13. As a result, the resultant CMOS device becomes highly resistant to the short-channel effect. Consequently, the dose amount of impurities can be reduced and an increase of the threshold voltage Vth of the MOSFET can be suppressed while suppressing deterioration of a saturated current due to impurity scattering.

When the thickness of the strained Si layer 14b of the PMOS transistor is reduced, it is possible to more efficiently suppress deterioration of the hole mobility-improving rate versus the stress of the strained Si layer 14b. In other words, the strain is gradually relaxed in the course of the process for forming a MOSFET. The degree of the relaxation of the strain of the strained Si layer 14 is decreased by reducing the thickness of the strained Si layer 14. In addition, the mobility-improving rate depending upon the degree of the strain of the strained Si layer 14 varies between holes and electrons. As described, the thickness of the strained Si layer effective in suppressing the strain from relaxing differs in the NMOS transistor and the PMOS transistor, so that the thickness of the strained Si layers 14a and 14b differs.

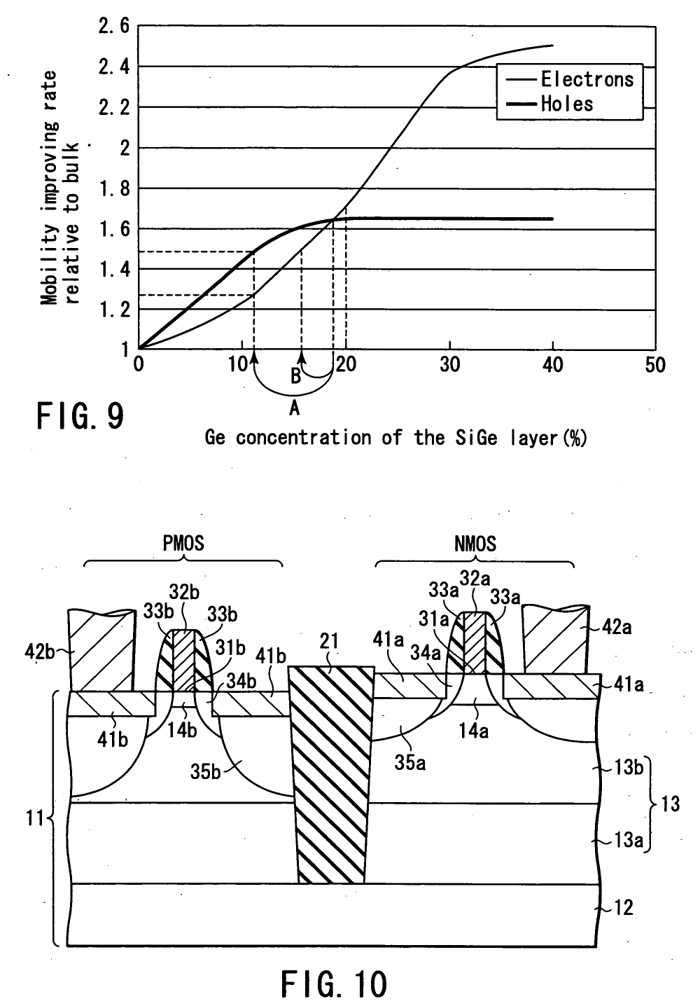

In this embodiment, assuming that the gate lengths of the gate electrodes 32a and 32b are set at 50 nm, the length of sidewall insulation layers 33a and 33b are set at 50 nm, the length of each of the gate portion formed of the gate electrode 32a (32b) and the right and left sides of sidewall insulation layer 33a (33b) becomes 150 nm. Assuming that the strained Si layers 14a and 14b except the gate portions are completely removed by over etching when the sidewall insulation layers 33a and 33b are formed, the thickness (h) of the strained Si layer 14a is 15 nm, the value of l/h becomes 5 (2l=150 nm) as shown in FIG. 8A. In this case, the relaxation rate becomes about 0.38, as shown in FIG. 8B. Note that FIG. 8B shows the stress relaxation of the epitaxial growth layer in the substrate having a hetero structure shown in FIG. 8A, when the epitaxial growth layer is processed. The mobility-improving rate of electron and hole is about 1.65 when the strained-Si layer epitaxially grows on the SiGe layer whose Ge concentration is 18%. Meanwhile, the strained layer is processed as shown in FIG. 8A and in the case of l/h=5, the hole mobility-improving rate is about 1.5 and the electron mobility-improving rate is about 1.25 (see the portion indicated by reference symbol A in FIG. 9).

On the other hand, assuming that the thickness (h) of the strained Si layer 14b of the PMOS transistor is 7.5 nm, l/h is 10 from FIG. 8A. In this case, as shown in FIG. 8B, the relaxation rate is about 0.16 and the hole mobility-improving rate of the PMOS transistor becomes-about 1.5 (see the portion indicated by reference symbol B in FIG. 9). The relaxing rate is lowered by reducing the thickness of the strained Si layer 14b. As a result, the hole mobility-improving rate can be suppressed from decreasing.

As described, the stress of the strained Si layer 14 can be relaxed in the course of the manufacturing process. The electron and hole mobility improving rates can be suppressed from decreasing by reducing the thickness of the strained Si layer 14b sufficiently (particularly the hole mobility-improving rate can be suppressed from decreasing).

In the case of the PMOS transistor, by reducing the thickness of the strained Si layer 14b sufficiently, an inversion layer may be formed in the Si₁₋ₓGeₓ (0≦x<1) layer 13b under the strained Si layer 14b. In this manner, the channel region can be induced in the Si₁₋ₓGeₓ (0≦x<1) layer 13b having a high hole mobility-improving rate. As a result, the driving current can be increased.

As described in the above, the strained Si layers of an NMOS transistor and a PMOS transistor can be formed with different thicknesses on a single substrate-strained Si of a SiGe layer and a strained Si layer. More specifically, the strained Si layer of the NMOS transistor is formed thicker than that of the PMOS transistor. In other words, the strained Si layer of the PMOS transistor is formed thinner than that of the NMOS transistor. With this structure, the relaxation of the mobility-improving rate can be varied between holes of the PMOS transistor and electrons of the NMOS transistor. More specifically, the thicknesses of the strained Si layer of the NMOS and PMOS transistors can be optimized, respectively, with the result that a high performance CMOS device can be manufactured.

FIG. 10 show the case where a substrate contact is further formed in the CMOS device as shown in FIG. 1. Like reference numerals designate like structural elements and any further explanation is omitted for brevity's sake.

As shown in FIG. 10, on the diffusion layer regions 35a, 35a of an NMOS transistor, silicide layers 41a, 41a are formed, respectively. Similarly, on the diffusion layer regions 35b, 35b of a PMOS transistor, silicide layers 41b, 41b are formed, respectively. To either one (or both) of the silicide layers 41a, 41a and either one (or both) of the silicide layers 41b, 41b, contact vias (e.g., tungsten (W)) 42a, 42b are connected and each serve as a substrate contact.

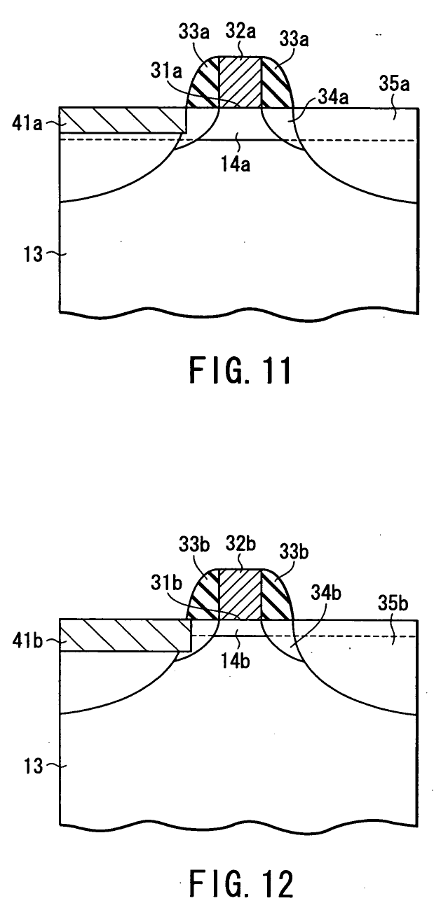

In the structure mentioned above, as shown in FIG. 11, if the thickness of the strained Si layer 14a of the NMOS transistor is increased, the Schottky contact between a silicide compound (semiconductor) of the strained Si layer and a metal (via 42a) 14a is easily formed. In this case, the silicide layer having a low Ge content is in contact with the via. More specifically, in the case of an NMOS transistor, it is easy to obtain the relationship: φ[metal]<φ[semiconductor], where φ is a work function, in which the silicide layer 41a and the via 42a can be made into ohmic contact with each other. In contrast as shown in FIG. 12, in the case of a PMOS transistor having a thinner strained Si layer 14b, the Schottky contact between a silicide compound (semiconductor) of the SiGe layer 13 and a metal (via 42b) can be easily made. In this case, the silicide layer having a high Ge content is in contact with a via. More specifically, it is easy to obtain the relationship: φ[metal]>φ[semiconductor], in which the silicide layer 41b and the via 42b can be made into ohmic contact with each other.

At the interface between the silicide layer (41a, 41b) and the via (42a, 42b), it is designed such that the silicide layer 41a of the NMOS transistor has a lower Ge concentration, whereas the silicide layer 41b of the PMOS transistor has a higher Ge concentration. More specifically, the Ge concentration of the SiGe layer 13 in the PMOS transistor is controlled to be higher than that in NMOS transistor. In this manner, the contact resistances of the portions at which the silicide layers 41a, 41b are in contact with the vias 42a, 42b in the NMOS transistor and PMOS transistor can be reduced.

Referring now to FIG. 9, the relationship of the hole and electron mobility-improving rate versus the degree of the strain (Ge concentration of the SiGe layer) will be further explained. As is apparent from FIG. 9, when the Ge concentration of the SiGe layer 13 is set at 20% or more, the hole mobility-improving rate is saturated, whereas the electron mobility-improving rate increases virtually in proportional to the Ge concentration. On the other hand, when the Ge concentration of the SiGe layer 13 is increased, exposed SiGe is dissolved by various wet treatments employed in forming a MOSFET.

Then, the Ge concentration of the SiGe layer 13 of the PMOS transistor is controlled to be higher than that of the NMOS transistor within the range of the Ge concentration in which SiGe is not dissolved. In this manner, it is possible to further increase the mobility of holes and further reduce the contact resistance.

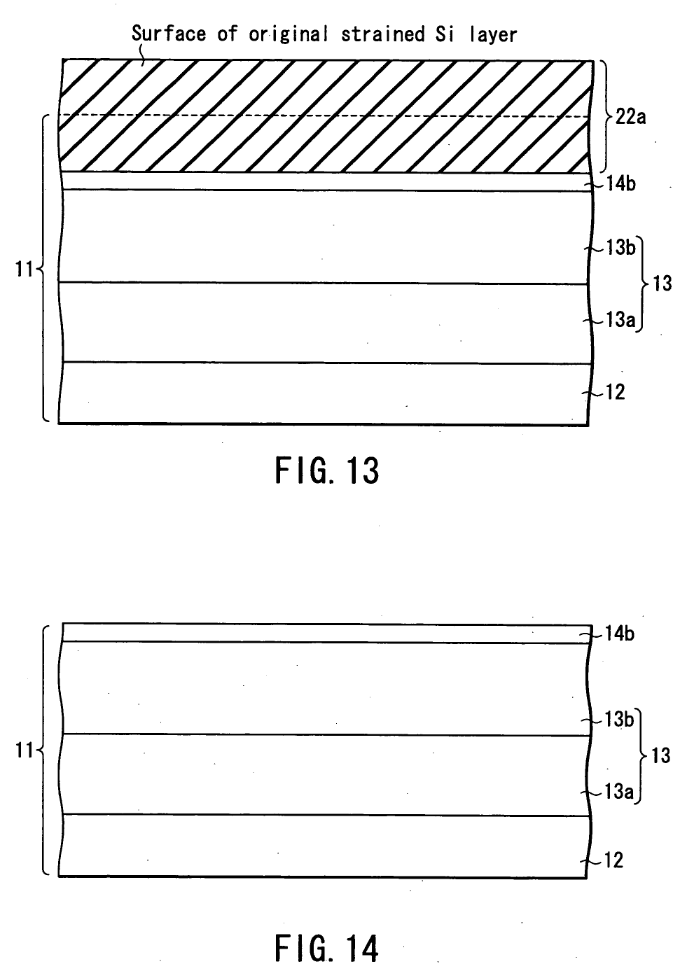

In the embodiment explained above, the thickness of the strained Si layer 14 is controlled by oxidation. More specifically, the strained Si layers 14a and 14b different in thickness are formed by Si oxidation. Alternatively, for example, as shown in FIGS. 13 to 15, the thickness of the strained Si layer 14a formed in the first region can be varied from that of the strained Si layer 14b formed in the second region by controlling the strained Si layer 14 so as to have different thicknesses within the wafer plane when Si is epitaxially grown.

More specifically, Si oxidation is applied uniformly (see FIG. 13) to the plane of a wafer-form substrate-strained Si 11 (see FIG. 3) formed by stacking the SiGe layer 13 and the strained Si layer 14 on the Si substrate 12. At this time, the thickness of Si oxide (SiO₂) film 22a is controlled such that the thickness of the strained Si layer 14 becomes equal to the predetermined thickness (second thickness) of the strained Si layer 14b of a PMOS transistor, in consideration of the consumed amount of Si during the later oxidation process for forming a MOSFET.

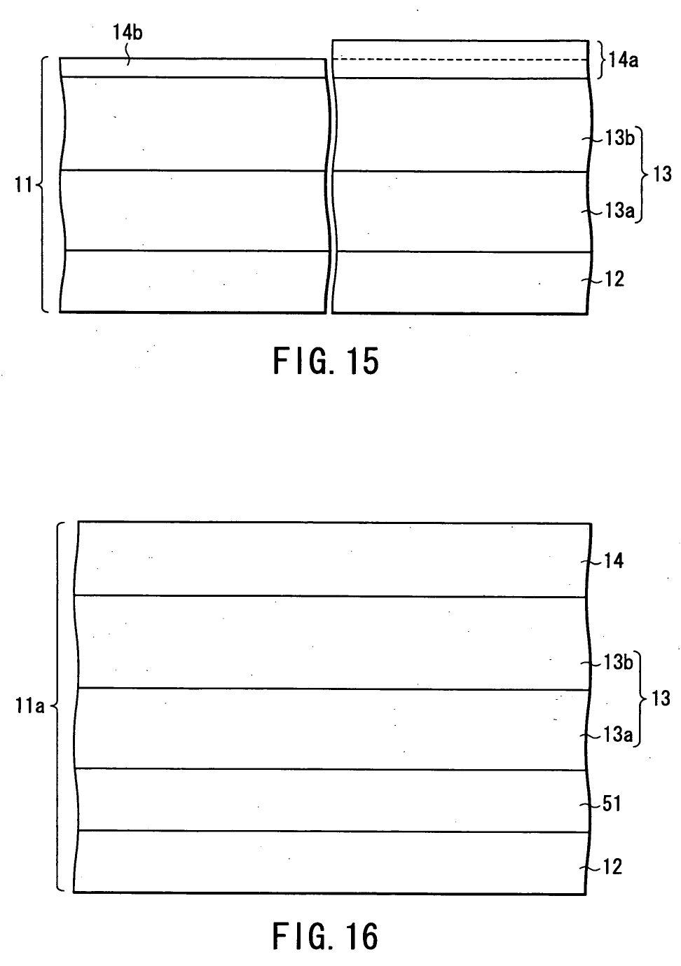

Subsequently, the SiO₂ film 22a is completely removed (see FIG. 14), and then the NMOS transistor is formed. Si epitaxially grows selectively only on the upper surface of the substrate-strained Si 11 corresponding to the first region (see FIG. 15). At that time, the thickness of the epitaxially-grows Si is controlled such that the thickness of the strained Si layer 14 in the first region becomes equal to, for example, the predetermined thickness (first thickness) of the strained Si layer 14a of the NMOS transistor, in consideration of the consumed amount of Si during the later oxidation process for forming a MOSFET. In this manner, a substrate-strained Si 11 having the strained Si layers 14a and 14b different in thickness can be obtained as the same as shown in FIG. 7.

On the substrate-strained Si 11 thus obtained, more specifically, on the first and second regions having the strained Si layer 14a and the strained Si layer 14b respectively formed, an NMOS transistor and a PMOS transistor are respectively formed in accordance with a known MOSFET manufacturing process. In this way, the CMOS device shown in FIG. 1 is accomplished.

The explanation has been made by taking a bulk-type substrate-strained Si 11 as an example. However, an Strained-Si/SiGe-On-Insulator (SGOI) substrate (substrate-strained Si) 11a shown in FIG. 16 may be used. The SGOI substrate 11a is formed by stacking the SiGe layer 13 and the strained Si layer 14 mentioned above on a Si substrate 12 with a Buried Oxide (BOX) 51 interposed between them.

The Ge concentration (diffusion rate) of the SiGe layer 13 may be constant or graded. The SiGe layer 13 may contain carbon (C).

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

1. A semiconductor device comprising:
a substrate-strained Si formed of a first semiconductor layer which has a first lattice constant and formed on a semiconductor substrate, and a second semiconductor layer which has a second lattice constant and epitaxially grows such that a lattice of the second semiconductor layer matches that of the first semiconductor layer;
a first conductive type metal oxide semiconductor (MOS) transistor which is formed in a first region on the substrate-strained Si and has the second semiconductor layer modified so as to have a first thickness; and
a second conductive type MOS transistor which is formed in a second region on the substrate-strained Si and has the second semiconductor layer modified so as to have a second thickness thinner than the first thickness.

2. The semiconductor device according to claim 1, wherein the first semiconductor layer comprises a lattice-strain buffer layer having a chemical compound compositionally graded and a lattice-strain relaxation layer stacked on the lattice-strain buffer layer and having the chemical compound compositionally uniform; the lattice-strain relaxation layer being a Si₁₋ₓGeₓ (0≦x<1) layer, and the lattice-strain buffer layer being a SiGe_{0→x} layer whose Ge concentration gradually decreases toward the interface with the semiconductor substrate.

3. The semiconductor device according to claim 2, wherein in the lattice-strain relaxation layer and lattice-strain buffer layer, a Ge concentration of the second region is higher than that of the first region.

4. The semiconductor device according to claim 1, wherein the first conductive type metal oxide semiconductor transistor is an n-channel MOS (NMOS) transistor, and the second conductive type metal oxide semiconductor transistor is a p-channel MOS (PMOS) transistor.

5. The semiconductor device according to claim 1, wherein the second conductive type metal oxide semiconductor transistor has an inversion-layer formed in the first semiconductor layer which lies immediately beneath the second semiconductor layer.

6. A method of manufacturing a semiconductor device using a substrate-strained Si by stacking a first semiconductor layer and a second semiconductor layer sequentially in this order on a surface of a semiconductor substrate comprising:
oxidizing a surface portion of the second semiconductor layer;
removing an oxide film formed on the surface portion of the second semiconductor layer;
forming an anti-oxide film on the surface portion of the second semiconductor layer corresponding to the first region;
oxidizing the surface portion of the second semiconductor layer corresponding to the second region except the first region on the substrate-strained Si with the anti-oxide film as a mask;
removing the oxide film formed by oxidation on the surface portion of the second semiconductor layer corresponding to the second region; and
forming a first conductive type metal oxide semiconductor (MOS) transistor having the second semiconductor layer of a first thickness in the first region on the substrate-strained Si, and forming a second conductive type MOS transistor having the second semiconductor layer of a second thickness in the second region on the substrate-strained Si, the second thickness being thinner than the first thickness.

7. The method according to claim 6, wherein the first semiconductor layer comprises a lattice-strain buffer layer having a chemical compound compositionally graded and a lattice-strain relaxation layer stacked on the lattice-strain buffer layer and having the chemical compound compositionally uniform; the lattice-strain relaxation layer is a Si₁₋ₓGeₓ (0≦x<1) layer, and the lattice-strain buffer layer is a SiGe_{0→x} layer whose Ge concentration gradually decreases toward the interface with the semiconductor substrate.

8. The method according to claim 7, wherein in the lattice-strain relaxation layer and lattice-strain buffer layer, a Ge concentration of the second region is higher than that of the first region.

9. The method according to claim 6, wherein the first conductive type metal oxide semiconductor transistor is an n-channel MOS (NMOS) transistor, and the second conductive type metal oxide semiconductor transistor is a p-channel MOS (PMOS) transistor.

10. The method according to claim 6, wherein the second conductive type metal oxide semiconductor transistor has an inversion layer formed in the first semiconductor layer which lies immediately beneath the second semiconductor layer.

11. A method of manufacturing a semiconductor device using a substrate-strained Si by stacking a first semiconductor layer and a second semiconductor layer sequentially in this order on a surface of a semiconductor substrate comprising:
oxidizing a surface portion of the second semiconductor layer;
removing an oxide film formed on the surface portion of the second semiconductor layer;
selectively growing only the second semiconductor layer corresponding to at least a first region on the substrate-strained Si; and
forming a first conductive type metal oxide semiconductor (MOS) transistor having the second semiconductor layer of a first thickness in the first region on the substrate-strained Si, and forming a second conductive type MOS transistor having the second semiconductor layer of a second thickness in the second region on the substrate-strained Si, the second thickness being thinner than the first thickness.

12. The method according to claim 11, wherein the first semiconductor layer comprises a lattice-strain buffer layer having a chemical compound compositionally graded and a lattice-strain relaxation layer stacked on the lattice-strain buffer layer and having the chemical compound compositionally uniform; the lattice-strain relaxation layer is a Si₁₋ₓGeₓ (0≦x<1) layer, and the lattice-strain buffer layer is a SiGe_{0→x} layer whose Ge concentration gradually decreases toward the interface with the semiconductor substrate.

13. The method according to claim 12, wherein in the lattice-strain relaxation layer and lattice-strain buffer layer, a Ge concentration of the second region is higher than that of the first region.

14. The method according to claim 11, wherein the first conductive type metal oxide semiconductor transistor is an n-channel MOS (NMOS) transistor, and the second conductive type metal oxide semiconductor transistor is a p-channel MOS (PMOS) transistor.

15. The method according to claim 11, wherein the second conductive type metal oxide semiconductor transistor has an inversion layer formed in the first semiconductor layer which lies immediately beneath the second semiconductor layer.
